(19) United States
(12) Patent Application Publication
(10) Pub. No.: US 2012/0007064 A1
(43) Pub. Date: Jan. 12, 2012

(54) ORGANIC ELECTROLUMINESCENT DEVICE AND METHOD FOR PREPARING THE SAME

(75) Inventors: Jeoung-Kwen NOH, Daejeon Metropolitan City (KR); Young-Chul Lee, Daejeon Metropolitan City (KR); Min-Soo Kang, Daejeon Metropolitan City (KR); Se Hwan Son, Daejeon Metropolitan City (KR); Hyeon Choi, Daejeon Metropolitan City (KR)

(73) Assignee: LG CHEM, LTD., Youndungpo-gu (KR)

(21) Appl. No.: 13/184,350

(22) Filed: Jul. 15, 2011

Related U.S. Application Data
(63) Continuation-in-part of application No. 12/149,747, filed on May 7, 2008, now abandoned.
Application No. 12/149,747 is a continuation of application No. PCT/KR2006/004620, filed on Nov. 7, 2006.
Application No. PCT/KR2006/004620 is a continuation-in-part of application No. 11/589,792, filed on Oct. 31, 2006.
Application No. 11/589,792 is a continuation-in-part of application No. 10/798,584, filed on Mar. 10, 2004, now Pat. No. 7,538,341.
Application No. 10/798,584 is a division of application No. 09/914,731, filed on Aug. 30, 2001, now Pat. No. 6,720,573.

(30) Foreign Application Priority Data
Dec. 31, 1999 (KR) 1999-067746
Dec. 26, 2000 (KR) 2000-82085
Nov. 1, 2005 (KR) 2005-0103664
Nov. 7, 2005 (KR) 10-2005-0105812

(51) Int. Cl. H01L 51/52; H01L 51/54

(52) U.S. Cl. 257/40; 257/E51.018; 257/E51.024

(57) ABSTRACT

The present invention relates to an organic electroluminescent device comprising a substrate, a cathode, at least three organic material layers comprising a light-emitting layer, and an anode in the sequentially laminated form, in which the organic material layers comprise an n-type organic material layer positioned between the cathode and the light-emitting layer; and an organic material layer comprising a compound having a functional group selected from the group consisting of an imidazole group, an oxazole group and a thiazole group between the cathode and the light-emitting layer. The organic electroluminescent device according to the present invention comprises an organic material layer comprising a compound having a functional group selected from the group consisting of an imidazole group, an oxazole group and a thiazole group between a cathode and a light-emitting layer, thus having an improved electron injection characteristic to provide an organic electroluminescent device of an inverted structure operating at a low voltage.

This application is a continuation-in-part of U.S. application Ser. No. 11/589,792, filed Oct. 31, 2006, which is a continuation-in-part of U.S. application Ser. No. 10/798,584, filed Mar. 10, 2004 (now U.S. Pat. No. 7,538,341) which is a divisional of U.S. application Ser. No. 09/914,731, filed Aug. 31, 2001 (now U.S. Pat. No. 6,720,573) which is a National Stage Entry of U.S. International Application No. PCT/KR00/01537, filed on Dec. 27, 2000 and claims priority to Korean Application Nos. 2005-0103664, filed Nov. 1, 2005, 2000-82085, filed Dec. 26, 2000 and 1999-067746, filed Dec. 31, 1999. This application is further a continuation-in-part of U.S. application Ser. No. 12/149,747, filed May 7, 2008, which is a continuation of International Application No. PCT/KR2006/004620, filed Nov. 7, 2006, and claim priority to Korean Application No. 10-2005-010582, filed Nov. 7, 2005, all of which are hereby incorporated by reference in their entirety for all purposes as if fully set forth herein.

### TECHNICAL FIELD

The present invention relates to an organic electroluminescent device and a method for preparing the same. More particularly, the present invention relates to an organic electroluminescent device of an inverted structure operating at a low driving voltage, and a method for preparing the same.

### BACKGROUND ART

Organic electroluminescent devices (OLED) are generally composed of two electrodes (an anode and a cathode) and at least one organic material layer located between these electrodes. When voltage is applied between the two electrodes of the organic electroluminescent device, holes and electrons are injected into the organic material layer from the anode and cathode, respectively, and are recombined in the organic material layer to form excitons. In turn, when these excitons decay to their ground state, photons corresponding to the energy difference are emitted. By this principle, the organic electroluminescent devices generate visible ray, and they are used in the fabrication of information display devices and illumination devices.

The organic electroluminescent devices are classified into three types: a bottom emission type in which light produced in the organic material layer is emitted in the direction of a substrate; a top emission type in which the light is emitted in direction opposite the substrate; and a both-side emission type in which the light is emitted in both the direction of the substrate and the direction opposite the substrate.

In passive matrix organic electroluminescent device (PMOLED) displays, an anode and a cathode perpendicularly cross each other, and the area of the crossing point acts as a pixel. Thus, the bottom emission and top emission types have no great difference in effective display area ratios (aperture ratios).

However, active matrix organic electroluminescent device (AMOLED) displays include thin-film transistors (TFTs) as switching devices for driving the respective pixels. Because the fabrication of these TFTs generally requires a high-temperature process at least several hundred C.°), a TFT array required for the driving of organic electroluminescent devices is formed on a glass substrate before the deposition of electrodes and organic material layers. In this regard, the glass substrate having the TFT array formed thereon is defined as a backplane. When the active matrix organic electroluminescent device displays having this backplane are fabricated to have the bottom emission structure, a portion of light emitted toward the substrate is blocked by the TFT array, resulting in a reduction in the effective display aperture ratio. This problem becomes more severe when pluralities of TFTs are given to one pixel in order to fabricate more elaborate displays. The bottom-emission structure is known to have the display aperture, ratio of less than 40%. When WXGA (Wide Extended Graphics Array) is applied to 14″ grade using TFT, the display aperture ratio should be equal to or less than 20%. The reduction of the display aperture ratio affects the electric power consumed for driving and life time of the organic electroluminescent device. For this reason, the active matrix organic electroluminescent devices need to be fabricated to have the top emission structure.

In the top emission type or both-side emission type organic electroluminescent devices, an electrode located on the opposite side of the substrate without making contact with the substrate must be transparent in the visible ray region. In the organic electroluminescent devices, a conductive oxide film made of, for example, indium zinc oxide (IZO) or indium tin oxide (ITO), is used as the transparent electrode. However, this conductive oxide film has a very high work function of generally more than 4.5 eV. For this reason, if the cathode is made of this oxide film, the injection of electrons from the cathode into the organic material layer becomes difficult, resulting in a great increase in the operating voltage of the organic electroluminescent devices and deteriorations in important device characteristics, such as light emission efficiency. The top emission or both-side emission type organic electroluminescent devices need to be fabricated to have the so-called “inverted structure” formed by the sequential lamination of the substrate, the cathode, the organic material layer and the anode.

An electron injection characteristic from a cathode to an electron transport layer in a regular organic electroluminescent device, is improved by depositing a thin LiF layer, which helps the injection of electrons, between the electron transport layer and the cathode. However, in this case, the electron injection characteristic is improved only when the method is used in a device in which the cathode is used as a top contact electrode, while the electron injection characteristic is very poor when the method is used in a device having an inverted structure in which the cathode is used as a bottom contact electrode.

“An effective cathode structure for inverted top-emitting organic electroluminescent device,” Applied Physics Letters, Volume 85, September 2004, p. 2469, describes an attempt to improve the electron injection characteristic through a structure having a very thin Alq3-LiF—Al layer between a cathode and an electron transport layer. However, the structure has a disadvantage that the fabricating process is very complicated. In addition, “Efficient bottom cathodes for organic electroluminescent device,” Applied Physics Letters, Volume 85, August 2004, p. 837, describes an attempt to improve the electron injection characteristic by depositing a thin Al layer between a metal-halide layer (NaF, CsF, KF) and an electron transport layer. However, the method also has a problem in the process because a new layer must be used.

WO03/83958 describes an organic electroluminescent device of an inverted structure having an charge transport layer n-doped (Bphen:Li) between an cathode and an light-emitting layer. However, the organic electroluminescent device also has a problem in the complicated process for fabricating due to application of the n-doping process.

Meanwhile, in a process of fabricating the organic electroluminescent device with the above-described inverted structure, if the anode located on the organic material layer is formed of a transparent conductive oxide film, such as IZO or ITO, by the use of resistive heating evaporation, the resistive heating evaporation will cause the collapse of the inherent chemical composition ratio of the oxide due to, for example, thermal decomposition during a thermal evaporation procedure. This will result in the loss of characteristics, such as electrical conductivity and visible ray permeability. For this reason, the resistive heating evaporation cannot be used in the deposition of the conductive oxide film, and in most cases, techniques, such as plasma sputtering, are now used.

However, if the electrode is formed on the organic material layer by techniques such as sputtering, the organic material layer can be damaged due to, for example, electrically charged particles present in plasma used in the sputtering process. The damage of the organic material layer generates the reduction of characteristics for injecting and transporting electrons or holes and for emitting light.

To avoid damage to the organic material layer, which can occur when forming an electrode on the organic material layer, for example, methods for lowering RF power or DC voltage in an RF or DC sputtering process to reduce the number and mean kinetic energy of atoms incident from a sputtering target onto the substrate of the organic electroluminescent device, thus reducing sputtering damage to the organic material layer, and methods for increasing the distance between the sputtering target and the substrate of the organic electroluminescent device to enhance the opportunity of the collisions between atoms, incident to the substrate of the organic electroluminescent device from a sputtering target, and sputtering gases (e.g., Ar), thus intentionally reducing the kinetic energy of the atoms.

However, as most of the above-described methods result in a very low deposition rate, the processing time of the sputtering step becomes very long, resulting in a significant reduction in productivity throughout a batch process for fabricating the organic electroluminescent device. Furthermore, even in an instance when the sputtering process has a low deposition rate as described above, the possibility of particles having high kinetic energy reaching the surface of the organic material layer still exists, and thus, it is difficult to effectively prevent sputtering damage to the organic material layer.

“Transparent organic light emitting devices,” Applied Physics Letters, May 1996, Volume 68, p. 2606, describes a method of forming an anode and organic material layers on a substrate, and then forming a thin layer of mixed metal film of Mg:Ag having excellent electron injection performance thereon, and lastly, forming a cathode using ITO by sputtering deposition thereon, as shown in FIG. 1. However, the Mg:Ag metal film has shortcomings in that the metal film is lower in visible ray permeability than ITO or IZO and also its process control is somewhat complicated.

“A metal-free cathode for organic semiconductor devices,” Applied Physics Letters, Volume 72, April 1998, p. 2138, describes an organic electroluminescent device having a structure formed by the sequential lamination of a substrate, an anode, an organic material layer and a cathode, where a CuPc layer, relatively resistant to sputtering, is deposited between the organic material layer and the cathode in order to prevent sputtering damage to the organic material layer, which is caused by the deposition of the cathode, as shown in FIG. 2. However, while CuPc is generally used to form a hole injection layer, in the above literature, CuPc serves as an electron injection layer in a state damaged by sputtering, between the organic material layer and the cathode in the organic electroluminescent device with a structure formed by the sequential lamination of the substrate, the anode, the organic material layer and the cathode. This deteriorates device characteristics, such as the charge injection characteristic and electric current efficiency of the organic electroluminescent device. Furthermore, CuPc has large light absorption in the visible ray region, and thus, increasing the thickness of the CuPc film leads to rapid deterioration of the device performance.

“Interface engineering in preparation of organic surface emitting diodes,” Applied Physics Letters, Volume 74, May 1999, p. 3209, describes an attempt to improve the low electron injection characteristic of the CuPc layer by depositing a second electron transport layer (e.g., Li thin film) between an electron transport layer and the CuPc layer, as shown in FIG. 3. However, this method for preventing sputtering damage has problems in that an additional thin metallic film is required and process control also becomes difficult.

In the process for fabricating an organic electroluminescent device of an inverted structure, methods to prevent the decrease in the electron injection characteristic due to contact related problems between the cathode and organic materials and the damage of the organic material layer when forming the anode, are required.

### DISCLOSURE

### Technical Problem

The present inventors have found a group of compounds that can act as materials for an electron transport layer in an organic electroluminescent device of an inverted structure to improve the electron injection characteristic from a bottom cathode to an electron transport layer, thereby providing the organic electroluminescent device of the inverted structure that can operate in low voltage. In addition, the present inventors have found that an n-type organic material layer positioned between an anode and a light-emitting layer can reduce an electrical barrier for hole injection efficiency, and thus efficiency of devices can be improved and various materials can be used as materials for electrodes. In addition, the present inventors have found a group of compounds that can act as materials of a buffer layer to prevent damage to an organic material layer, which can occur when forming the anode on the organic material layer, without deterioration of light emission characteristic.

Therefore, it is an objective of the present invention to provide an organic electroluminescent device of an inverted structure that operate at a low voltage and have an improved electron injection characteristic by using a compound having a functional group selected from the group consisting of an imidazole group, an oxazole group and a thiazole group. It is an another objective of the present invention to provide an organic electroluminescent device that has improved hole injection efficiency as well as improved electron injection efficiency, thus having high device efficiency and that can use various materials as electrode materials. It is an another objective of the present invention to provide an organic electroluminescent device of an inverted structure comprising a layer to prevent damage of an organic material layer, which can occur when forming the anode on the organic material layer. It is an another objective of the present invention to provide an organic light-emitting device of a top emission type or a both-side emission type based on the above device of the inverted structure.

### Technical Solution

The present invention provides an organic electroluminescent device having an inverted structure, characterized in that it comprises a substrate, a cathode, at least three organic material layers including a light-emitting layer, and an anode in the sequentially laminated form, in which the organic material layers include an n-type organic material layer positioned between the cathode and the light-emitting layer; and an organic material layer, comprising a compound having a functional group selected from the group consisting of an imidazole group, an oxazole group and a thiazole group, positioned between the cathode and the light-emitting layer.

According to the preferred embodiment of the present invention, the n-type organic layer is in contact with the anode. In this case, energy levels of the n-type organic material layer and the anode are preferred to satisfy the following Expression (1):

E_{nL}−E_{F1}≦4 eV (1)

In the Expression (1), E_{F1} is a Fermi energy level of the anode, E_{nL} is an LUMO energy level of the n-type organic material layer.

The Expression (1) may satisfy the following Expression:

2 eV<E_{nL}−E_{F1}≦4 eV

According to the preferred embodiment of the present invention, the organic electroluminescent device further comprises a p-type organic material layer that is interposed between the n-type organic material layer and the light-emitting layer and forms an NP junction together with the n-type organic material layer. In this case, energy levels of the n-type organic material layer and the p-type organic material layer are preferred to satisfy the following Expression (2):

E_{pH}−E_{nL}≦1 eV (2)

In the Expression (2), E_{nL} is an LUMO energy level of the n-type organic material layer and E_{pH} is an HOMO energy level of the p-type organic material layer forming the NP junction together with the n-type organic material layer.

The compound having a functional group selected from the group consisting of an imidazole group, an oxazole group and a thiazole group includes the compound of the following formula 1 or 2:

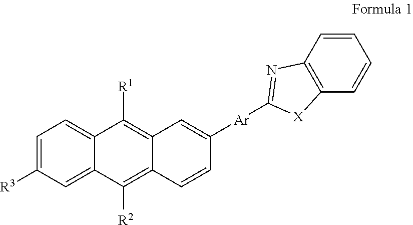

wherein, R¹ and R² may be the same or different from each other, and are each respectively selected from the group consisting of hydrogen, aliphatic hydrocarbons of 1-20 carbon atoms, aromatic rings and aromatic heterocyclic rings; Ar is selected from the group consisting of aromatic rings and aromatic heterocyclic rings; R³ is selected from the group consisting of hydrogen, aliphatic hydrocarbons having 1-6 carbon atoms, aromatic rings and aromatic heterocyclic rings; and X is selected from the group consisting of O, S and NR¹¹ wherein R¹¹ is selected from the group consisting of hydrogen, aliphatic hydrocarbons of 1-7 carbon atoms, aromatic rings and aromatic heterocyclic rings, provided that both of R¹ and R² are not hydrogen at the same time, and

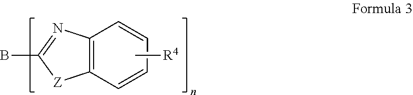

wherein Z is O, S or NR²²; R⁴ and R²² are respectively hydrogen, alkyl of 1-24 carbon atoms, aryl or hetero-atom substituted aryl of 5-20 carbon atoms, halogen atoms, or alkylene or alkylene comprising a hetero-atom necessary to complete a fused ring with a benzazole ring; B is a linkage unit consisting of alkylene, arylene, substituted alkylene, or substituted arylene, which conjugatedly or unconjugately connects the multiple benzazoles together; and n is an integer from 3 to 8.

The n-type organic material layer may comprise a compound of the following formula 3:

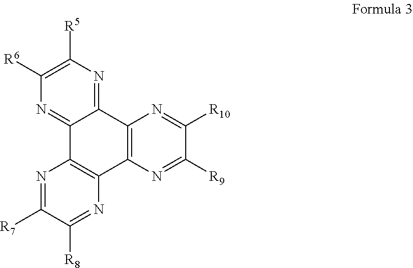

wherein, R⁵ to R¹⁰ are each respectively selected from the group consisting of hydrogen, halogen atoms, nitrile (—CN), nitro (—NO₂), sulfonyl (—SO₂R³¹), sulfoxide (—SOR³¹), sulfonamide (—SO₂NR³¹), sulfonate (—SO₃R³¹), trifluoromethyl (—CF₃), ester (—COOR³¹), amide (—CONHR³¹ or —CONR³¹R³²), substituted or unsubstituted straight or branched C₁-C₁₂ alkoxy, substituted or unsubstituted straight or branched C₁-C₁₂ alkyl, substituted or unsubstituted aromatic or non-aromatic heterocyclic rings, substituted or unsubstituted aryl, substituted or unsubstituted mono- or di-arylamine, and substituted or unsubstituted aralkylamine, and R³¹ and R³² are each respectively selected from the group consisting of substituted or unsubstituted C₁-C₆₀ alkyl, substituted or unsubstituted aryl, and substituted or unsubstituted 5- to 7-membered heterocyclic rings.

The n-type organic material layer may comprises at least one compound selected from 2,3,5,6-tetrafluoro-7,7,8,8-tetracyanoquinodimethane (F4TCNQ), fluoro-substituted 3,4,9,10-perylenetetracarboxylic dianhydride (PTCDA), cyano-substituted 3,4,9,10-perylenetetracarboxylic dianhydride (PTCDA), naphthalene-tetracarboxylic-dianhydride (NTCDA), fluoro-substituted naphthalene-tetracarboxylic-dianhydride (NTCDA), or cyano-substituted naphthalene-tetracarboxylic-dianhydride (NTCDA).

### Advantageous Effects

The organic electroluminescent device according to the present invention comprises an organic material layer comprising a compound having a functional group selected from the group consisting of an imidazole group, an oxazole group and thiazole group between the cathode and the light-emitting layer, thus having an improved electron injection characteristic to provide an organic electroluminescent device of an inverted structure operating at a low voltage. In addition, the organic electroluminescent device according to the present invention comprises an n-type organic material layer positioned between an anode and a light-emitting layer, and thus it has improved device efficiency and it can use various materials as anode materials. In addition, the organic electroluminescent device according to the present invention comprises a layer that can function as a buffer layer between the light-emitting layer and the anode, thus preventing damage to the organic material layer, which can occur when forming the anode on the organic material layer in a process of fabricating the organic electroluminescent device of the inverted structure. By preventing any damage to the organic material layer, various materials can be used as anode materials.

### DESCRIPTION OF DRAWINGS

The above and other objects, features and advantages of the present invention will be more clearly understood from the following detailed description taken in conjunction with the accompanying drawings, in which:

FIG. 1 illustrates the structure of the prior organic electroluminescent device formed by sequentially laminating a substrate, an anode, organic material layers and a cathode (ITO), in which an Mg:Ag layer is applied between one of the organic material layers and the ITO cathode;

FIG. 2 illustrates the structure of the prior organic electroluminescent device formed by sequentially laminating a substrate, an anode, organic material layers and a cathode (ITO), in which a CuPc layer is applied between one of the organic material layers and the ITO cathode;

FIG. 3 illustrates the structure of the prior organic electroluminescent device shown in FIG. 2, in which a Li thin film (electron injection layer) is laminated as an organic material layer in contact with the CuPc layer in the electroluminescent device;

FIG. 4 illustrates the structure of a top emission type organic electroluminescent device according to the present invention;

FIG. 5 illustrates the structure of a both-side emission type organic electroluminescent device according to the present invention;

FIG. 6 illustrates a structure of a device having a symmetrical structure consisting of Al—LiF-electron transport layer-LiF—Al fabricated in Example 1.

FIG. 7 is, a graphic diagram showing a forward voltage-current characteristic and reverse voltage-current characteristic by electrons in the device having a symmetrical structure fabricated in Example 1.

FIG. 8 is a graphic diagram showing a change in the reverse voltage-current (leakage current) characteristic of an organic electroluminescent device as a function of the thickness of the inventive layer comprising a compound of formula 3;

FIG. 9 is a graphic diagram showing a change in the forward voltage-current characteristic of an organic electroluminescent device as a function of the thickness of the inventive layer comprising a compound of formula 3;

FIG. 10 is a graphic diagram showing the luminous intensity-current density characteristic of an organic electroluminescent device as a function of the thickness of the inventive layer comprising a compound of formula 3; and

FIG. 11 is a graphic diagram showing the luminance efficiency-current density characteristic of an organic electroluminescent device as a function of the thickness of the inventive layer comprising a compound of formula 3.

FIG. 12 shows views illustrating energy levels of an anode before and after applying an n-type organic material layer as an organic material layer in contact with an anode in an organic electroluminescent device according to an exemplary embodiment of the invention.

FIG. 13 is a view illustrating an ideal energy level of a conventional organic electroluminescent device.

FIG. 14 is a view illustrating an energy level of an organic electroluminescent device according to an exemplary embodiment of the invention.

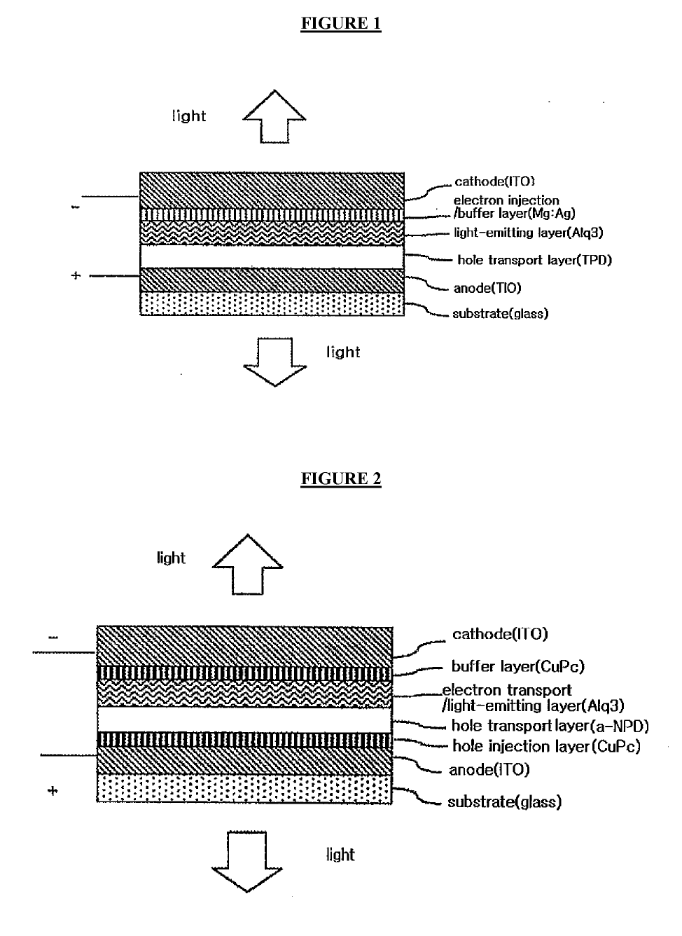

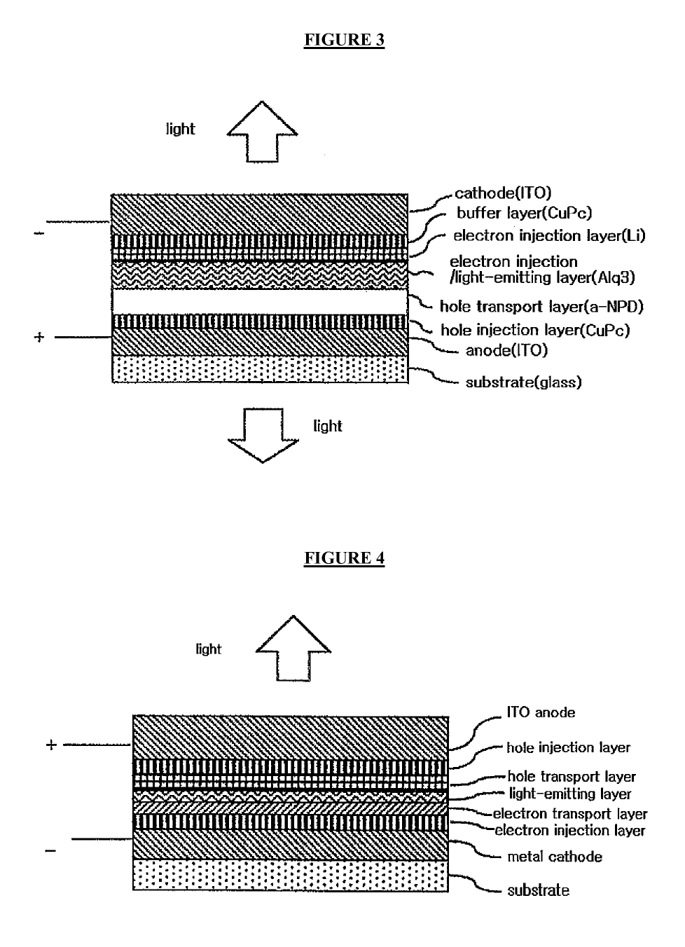

### BEST MODE

Hereinafter, the present invention will be described in detail.

The present invention can improve electron injection efficiency of an organic electroluminescent device having an inverted structure by comprising an organic material layer comprising a compound having a functional group selected from the group consisting of an imidazole group, an oxazole group and a thiazole group, positioned between the cathode and the light-emitting layer. As described above, since an organic electroluminescent device having an inverted structure uses a cathode as a bottom electrode, it has worse electron injection characteristic than a device having a normal structure, in spite of using an electron injecting layer such as a LiF layer. However, the present invention can provide an organic electroluminescent device having an inverted structure that has improved electron injection characteristic by using the compound containing the above certain functional group.

In addition, the present invention is characterized in comprising an n-type organic material layer positioned between the anode and the light-emitting layer. Conventional organic electroluminescent devices generally use a p-type organic material layer that can inject or transfer holes between an anode and a light-emitting device. However, the present invention uses an n-type organic material layer that transfers carriers through its LUMO energy level between an anode and alight-emitting layer, and thus the n-type organic material layer can generate carriers at the interface between the n-type organic material layer and its adjacent layer. Therefore, hole injection efficiency can be greatly improved. In the present specification, an n-type organic material layer means an organic material layer having n-type semiconductor features and a p-type organic material layer means an organic material layer having p-type semiconductor features.

According to the preferred embodiment of the present invention, the n-type organic layer is in contact with the anode. In this case, that energy levels of the n-type organic material layer and the anode are preferred to satisfy the following Expression (1):

E_{nL}−E_{F1}≦4 eV (1)

In the Expression (1), E_{F1} is a Fermi energy level of the anode, E_{nL} is an LUMO energy level of the n-type organic material layer.

The Expression (1) may satisfy the following Expression:

2 eV<E_{nL}−E_{F1}≦4 eV

According to the preferred embodiment of the present invention, the organic electroluminescent device further comprises a p-type organic material layer that is interposed between the n-type organic material layer and the light-emitting layer and forms an NP junction together with the n-type organic material layer. In this case, energy levels of the n-type organic material layer and the p-type organic material layer are preferred to satisfy the following Expression (2):

E_{pH}−E_{nL}≦1 eV (2)

In the Expression (2), E_{nL} is an LUMO energy level of the n-type organic material layer and E_{pH} is an HOMO energy level of the p-type organic material layer forming the NP junction together with the n-type organic material layer.

According the above embodiments, the NP junction is formed between the n-type organic material layer and the p-type organic material layer. When the NP junction is formed, the energy level difference between the LUMO energy level of the n-type organic material layer and the HOMO energy level of the p-type organic material layer is reduced. Therefore, holes or electrons are easily generated by an external voltage. That is, the NP junction causes holes and electrons to be easily generated in the p-type organic material layer and the n-type organic material layer, respectively. Since holes and electrons are simultaneously generated in the NP junction, the electrons are transported to the anode through the n-type organic material layer and holes are transported to the p-type organic material layer.

The n-type organic material layer in contact with the anode has a predetermined LUMO energy level with respect to a Fermi energy level of the anode and an HOMO energy level of the p-type organic material layer. The n-type organic material layer is selected so as to reduce an energy difference between the LUMO energy level of the n-type organic material layer and the Fermi energy level of the anode and an energy difference between the LUMO energy level of the n-type organic material layer and the HOMO energy level of the p-type organic material layer. Therefore, holes are easily injected into the HOMO energy level of the p-type organic material layer through the LUMO energy level of the n-type organic material layer. However, in the invention, although the energy difference between the LUMO energy level of the n-type organic material layer and the Fermi energy level of the anode is up to 4 eV, holes can be efficiently injected. Therefore, in the invention, various materials can be used to form the electrode. The detailed description thereof will be described below.

The present invention can reduce the energy barrier for holes injection at the interface between the anode and organic material layers by using the n-type organic material layer, and thus the present invention can improve holes injection characteristic whereby excellent device performance exhibits. Also, according to the present invention, an anode can be formed of various materials, whereby a device manufacturing process can be simplified.

Particularly, the present invention can be applied to devices in which an energy difference between the LUMO energy level of the n-type organic material layer and the Fermi energy level of the anode exceeds 2 eV. Therefore, materials that can inject electrons easily, such as LiF—Al, Li—Al, Ca, Ca—Ag, Ca-IZO, etc. can be applied to an anode as well as a cathode, and thus an anode and a cathode can be formed of the same material. In this case, it is possible to realize various devices, such as a stack-type electronic device in which unit electronic devices are stacked and to simplify a device manufacturing process.

According to the above embodiments, the energy difference between the LUMO energy level of the n-type organic material layer and the Fermi energy level of the anode is equal to or less than 4 eV. Further, the energy difference between the LUMO energy level of the n-type organic material layer and the HOMO energy level of the p-type organic material layer is 1 eV or less, and preferably, approximately 0.5 eV or less. This energy difference is preferably approximately 0.01 eV to 1 eV in view of material selection.

When the energy difference between the LUMO energy level of the n-type organic material layer and the Fermi energy level of the anode is more than 4 eV, an effect of a surface dipole or a gap state on an energy barrier for hole injection is reduced. Also, when the energy difference between the LUMO energy level of the n-type organic material layer and the HOMO energy level of the p-type organic material layer is more than approximately 1 eV, the NP junction of the p-type organic material layer and the n-type organic material layer is not easily formed and thus a driving voltage for hole injection increases.

FIGS. 12 (a) and (b) illustrate energy levels of a anode for hole injection before and after an n-type organic material layer is applied between the anode and the light-emitting layer in a device according to an exemplary embodiment of the invention, respectively. In FIG. 12 (a), the anode has a Fermi energy level E_{F1} lower than a Fermi energy level E_{F2} of the n-type organic material layer. A vacuum level (VL) represents an energy level at which electrons can freely move in the anode and the n-type organic material layer.

In a case where the organic electroluminescent device uses the n-type organic material layer as an organic material layer in contact with the anode, since electrons move from the anode to the n-type organic material layer, the Fermi energy levels E_{F1} and E_{F2} of both layers come to be the same as shown in FIG. 12 (b). As a result, a surface dipole is formed at the interface of the anode and the n-type organic material layer, and the vacuum level, the Fermi energy level, the HOMO energy level, and the LUMO energy level are changed as shown in FIG. 12 (b).

Therefore, although difference between the Fermi energy level of the anode and the LUMO energy level of the n-type organic material layer is great, the energy barrier for hole injection can be reduced by keeping the anode in contact with the n-type organic material layer. When the Fermi energy level of the anode is lower than the LUMO energy level of the n-type organic material layer, electrons move from the anode to the n-type organic material layer, and thus a gap state is formed at an interface between the anode and the n-type organic material layer. As a result, the energy barrier for electron transport is minimized.

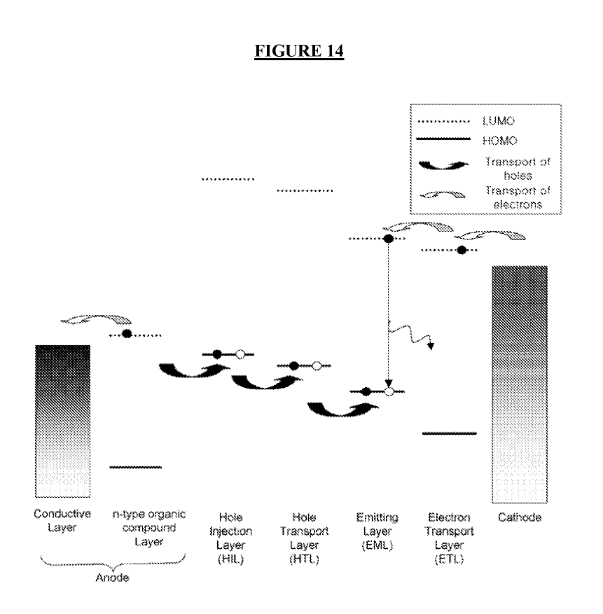

FIG. 13 illustrates an energy level of a conventional organic electroluminescent device. FIG. 14 illustrates an energy level of an organic electroluminescent device according to an exemplary embodiment of the invention. Since the energy barrier for holes/electrons injection is reduced by the n-type organic material layer, holes can be easily transferred from the anode to the light-emitting layer through the LUMO energy level of the n-type organic material layer and the HOMO energy level of the p-type organic material layer.

By using the n-type organic material layer, the anode may be formed of various materials. For example, the anode has a Fermi energy level of about 2.5 to 5.5 eV. Examples of conductive materials for the anode include carbon, magnesium, sodium, potassium, titanium, indium, yttrium, lithium, gadolinium, silver, tin, lead, aluminum, calcium, vanadium, chromium, copper, zinc, silver, gold, other metals, and an alloy thereof; zinc oxides, indium oxides, tin oxides, indium tin oxides (ITO), indium zinc oxides (IZO), and metal oxides that are similar thereto; Al—Li, Ca—Ag, materials having a stacked structure of a metal and a metal oxide such as Ca-IZO, and materials having a multi-layered structure such as LiF/Al or LiO₂/Al. According to the present invention, since various materials can be used for forming the anode, an upper electrode of devices having an inverted structure may be formed of transparent materials and it also may be formed of opaque materials.

The n-type organic material layer is interposed between the anode and the p-type organic material layer and injects holes into the p-type organic material layer at a low electric field. The n-type organic material layer is selected such that the energy difference between an LUMO energy level of the n-type organic material layer and a Fermi energy level of the anode is equal to or less than 4 eV and the energy difference between the LUMO energy level of the n-type organic material layer and an HOMO energy level of the p-type organic material layer is approximately 1 eV or less. For example, the n-type organic material layer has an LUMO energy level in a range of approximately 4 eV to 7 eV and electron mobility in a range of approximately 10⁻⁸ cm²/Vs to 1 cm²/Vs, preferably, approximately 10⁻⁶ cm²/Vs to 10⁻² cm²/Vs. When the electron mobility is less than approximately 10⁻⁸ cm²/Vs, it is not easy for the n-type organic material layer to inject holes into the p-type organic material layer. The n-type organic material layer may be formed of a material capable of being vacuum-deposited or a material capable of being formed into a thin film by a solution process.

The p-type organic material layer may be a hole injection layer, a hole transfer layer or a light-emitting layer. The energy difference between an HOMO energy level of the p-type hole injection layer or the p-type hole transport layer forming the NP junction and an LUMO energy level of the n-type organic material layer is approximately 1 eV or less, and preferably, approximately 0.5 eV or less. Examples of the material of the p-type hole injection layer or the p-type hole transport layer include arylamine-based compounds, conductive polymers, or block copolymers having both a conjugated portion and an unconjugated portion, but are not intended to limit the present invention.

The compound of formula 1 is described in Korean Paten Laid-open Publication 2003-0067773 and the compound of formula 2 is described in U.S. Pat. No. 5,645,948. Preferred compound having an imidazole group includes compounds having the following formulae:

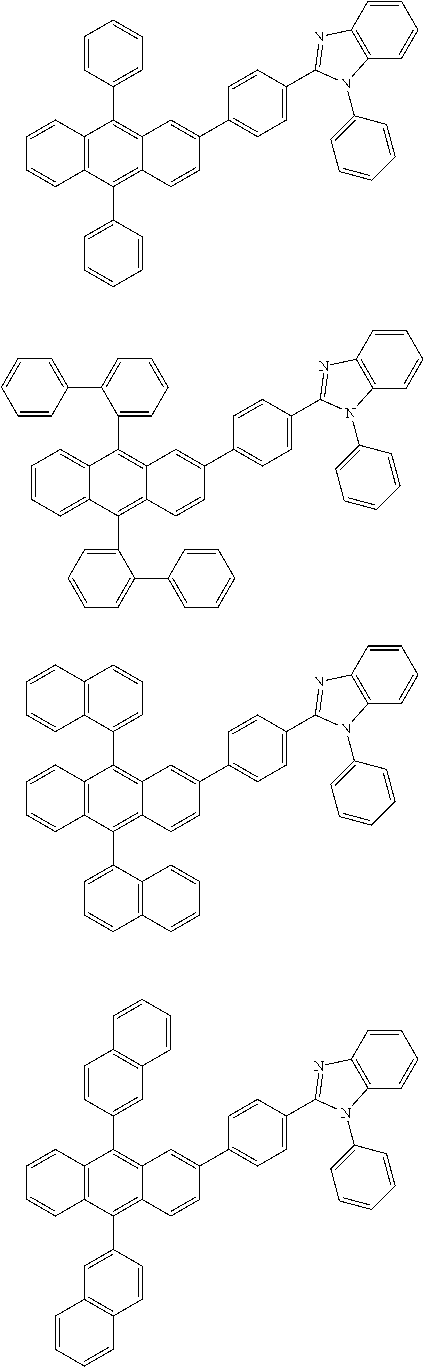

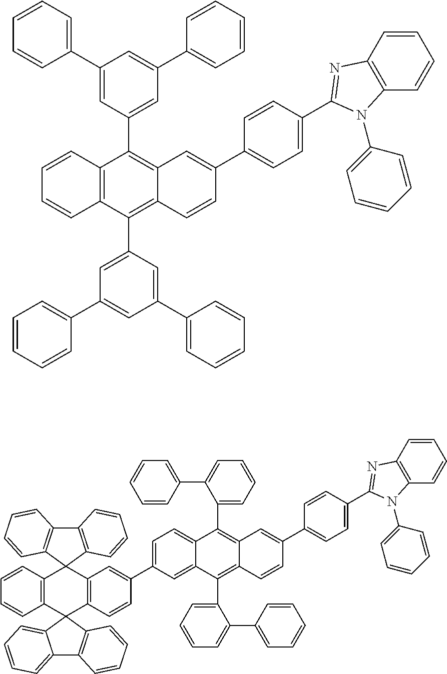

The organic material layer comprising a compound having a functional group selected from the group consisting of an imidazole group, an oxazole group and a thiazole group may be an electron transport layer and the electron transport layer can be formed by the co-deposition of an organic material with a metal having low work function, such as, Li, Cs, Na, Mg, Sc, Ca, K, Ce, Eu or a thin metal film containing at least one of these metals.

The organic electroluminescent device according to the present invention preferably comprises an electron injection layer with the organic material layer comprising a compound having a functional group selected from the group consisting of an imidazole group, an oxazole group and a thiazole group. A LiF layer is preferred as the electron injection layer.

The n-type organic material layer may comprise the compound of the following formula 3:

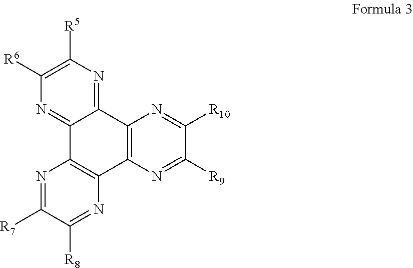

wherein, R⁵ to R¹⁰ are each respectively selected from the group consisting of hydrogen, halogen atoms, nitrile (—CN), nitro (—NO₂), sulfonyl (—SO₂R³¹), sulfoxide (—SOR³¹), sulfonamide (—SO₂NR³¹), sulfonate (—SO₃R³¹), trifluoromethyl (—CF₃), ester (—COOR³¹), amide (—CONHR³¹ or —CONR³¹R³²), substituted or unsubstituted straight or branched C₁-C₁₂ alkoxy, substituted or unsubstituted straight or branched C₁-C₁₂ alkyl, substituted or unsubstituted aromatic or non-aromatic heterocyclic rings, substituted or unsubstituted aryl, substituted or unsubstituted mono- or di-arylamine, and substituted or unsubstituted aralkylamine, and R³¹ and R³² are each respectively selected from the group consisting of substituted or unsubstituted C₁-C₆₀ alkyl, substituted or unsubstituted aryl, and substituted or unsubstituted 5- to 7-membered heterocyclic rings.

Preferred examples of the compound of formula I include compounds represented by the following formulae 3-1 to 3-6:

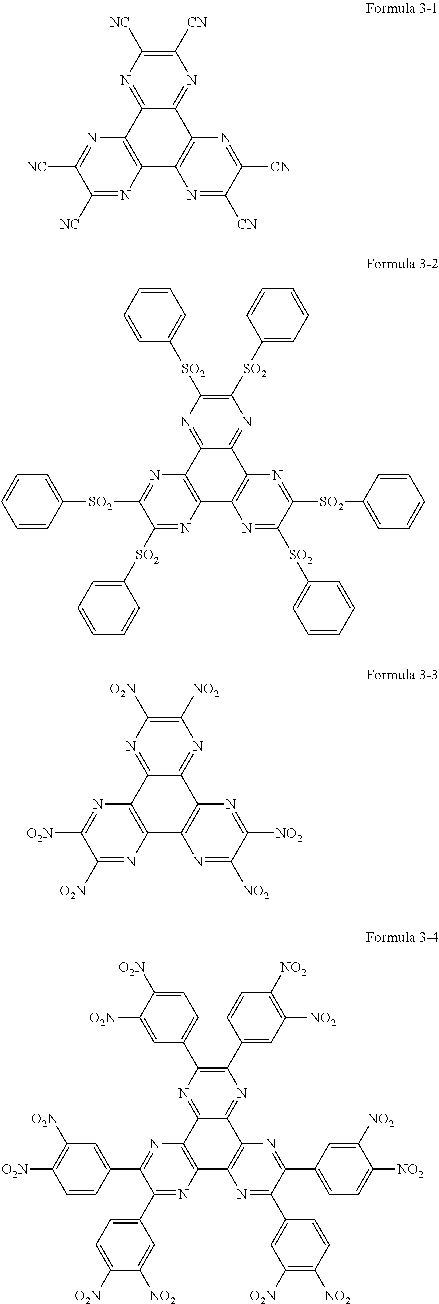

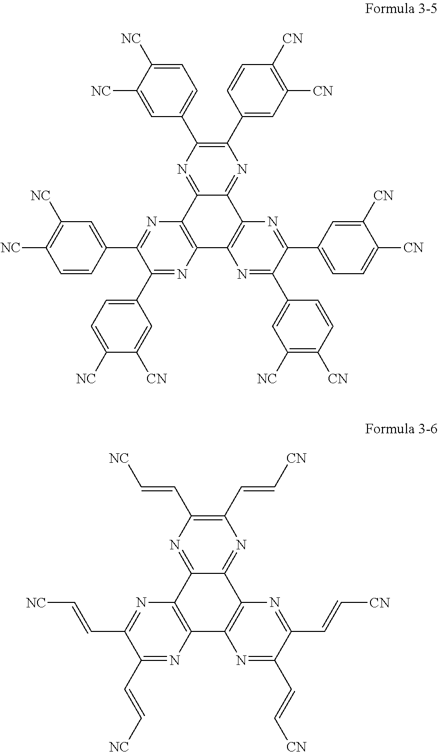

Other examples, synthetic methods and various features of the compound of formula 3 are described in the US patent application No. 2002-0158242, U.S. Pat. No. 6,436,559 and U.S. Pat. No. 4,780,536, the disclosures of which are all incorporated herein by reference.

The n-type organic material layer comprising the compound of the formula 3 functions as a buffer layer that prevent the damage of the organic material layer when forming the anode and is preferred to be formed to be in contact with the anode.

The organic material layer comprising the compound of formula 3 can prevent the organic material layer in contact with the anode from being damaged when forming the anode on the organic material layer during the process of fabricating the organic electroluminescent device. For example, if a technique, such as sputtering, is used for the formation of the anode, particularly a transparent anode, on the light-emitting layer, hole transport layer or hole injection layer, electrical or physical damage to the organic material layer can occur due to electrically charged particles or atoms having high kinetic energy, which are generated in plasma during a sputtering process. This damage to the organic material layer can likewise occur when forming an electrode on the organic material layer not only by sputtering but also by thin-film formation technology capable of causing damage to the organic material layer by involving charges or particles having high kinetic energy. However, when the anode is formed on the organic material layer comprising the compound of formula 3 using the above-described method, electrical or physical damage to the organic material layer can be minimized or prevented. This can be attributed to the fact that the compound of formula 3 has a higher crystallinity than that of organic materials used in the prior organic electroluminescent devices, so that the organic material layer comprising the compound has a higher density.

In the organic electroluminescent device according to the present invention, because it is possible to prevent damage to the organic material layer in a process of forming the anode, the control of process parameters and the optimization of a process apparatus during the formation of the anode becomes easier, so that process productivity throughout can also be improved. Also, the material and deposition method of the anode can be selected from a wide range thereof. For example, in addition to a transparent electrode such as IZO (indium doped zinc-oxide) or ITO (indium doped tin-oxide), a thin film made of metal, such as Al, Ag, Au, Ni, Pd, Ti, Mo, Mg, Ca, Zn, Te, Pt, Ir or an alloy material containing at least one of these metals can also be formed by sputtering or by physical vapor deposition (PVD) using laser, ion-beam assisted deposition or similar technologies which can cause damage to the organic material layer in the absence of the buffer comprising the compound of formula 3 by involving charges or particles having high kinetic energy.

In the organic electroluminescent device according to the present invention, the anode is preferred to consist of a metal or metal oxide having a work function of 2 to 6 eV, more preferably ITO or IZO.

In the present invention, the electrical properties of the organic electroluminescent device can be improved by the use of a organic material layer comprising the compound of formula 3. For example, the inventive organic electroluminescent device shows a reduction in leakage current in a reverse bias state, leading to a remarkable improvement in current-voltage characteristics, and thus, a very clear rectification characteristic. As used herein, the term “rectification characteristic,” which is a general characteristic of diodes means that the magnitude of current in a region applied with reverse voltage is much lower than the magnitude of current in a region applied with forward voltage. The compound of formula 3 has excellent crystallinity compared to organic materials, which have been used in the prior organic electroluminescent devices as described above so that a layer made of the compound of formula 3 has a high density. Thus, the compound of formula 3 effectively prevents structural defects of molecules or defects to interfacial characteristics, which occur when particles having high kinetic energy are implanted into the inside or interlayer interface of the organic material layer by a sputtering process or the like. For this reason, the electrical characteristics, such as rectification characteristic, of the device seem to be maintained.

Also, the organic material layer comprising the compound of formula 3 has higher visible ray permeability than an inorganic material layer used in the prior buffer layer that are made of, for example, metal or CuPc, so that its thickness is controlled more variably than the prior buffer layer. When the inorganic material layer which has been used as the buffer layer in the prior art is generally formed to a thickness of 200 nm, it has very low visible ray permeability, however, the layer comprising the compound of formula 3 did not show a reduction in visible ray permeability even when its thickness was 200 nm. In the present invention, the thickness of the organic material layer comprising the compound of formula 3 is preferably equal to or more than 20 nm, and more preferably equal to or more than 50 nm. If the thickness of the organic material layer is less than 20 nm, the layer cannot sufficiently function as the buffer layer. Meanwhile, the thickness of the organic material layer comprising the compound of formula 3 is preferred to be equal to or less than 250 nm. If the thickness of the layer is more than 250 nm, the process time required for the fabrication of the device will become long and the surface shape of the organic material layer comprising the compound of formula 3 will become rough, thus adversely affecting the other characteristics of the device.

Furthermore, in the organic electroluminescent device according to the present invention, the organic material layer comprising the compound of formula 3 acts as a hole injection layer for injecting holes from the anode into a hole transport layer or a light-emitting layer or as a charge generation layer for forming hole-electron pairs. Accordingly, the inventive organic electroluminescent device can become more efficient without requiring a separate hole injection layer or hole transport layer.

In the present invention, a thin oxide film having an insulating property may be additionally formed between the anode and the n-type organic material layer.

The organic electroluminescent device according to the present invention can be applied to a top emission structure or a both-side emission structure.

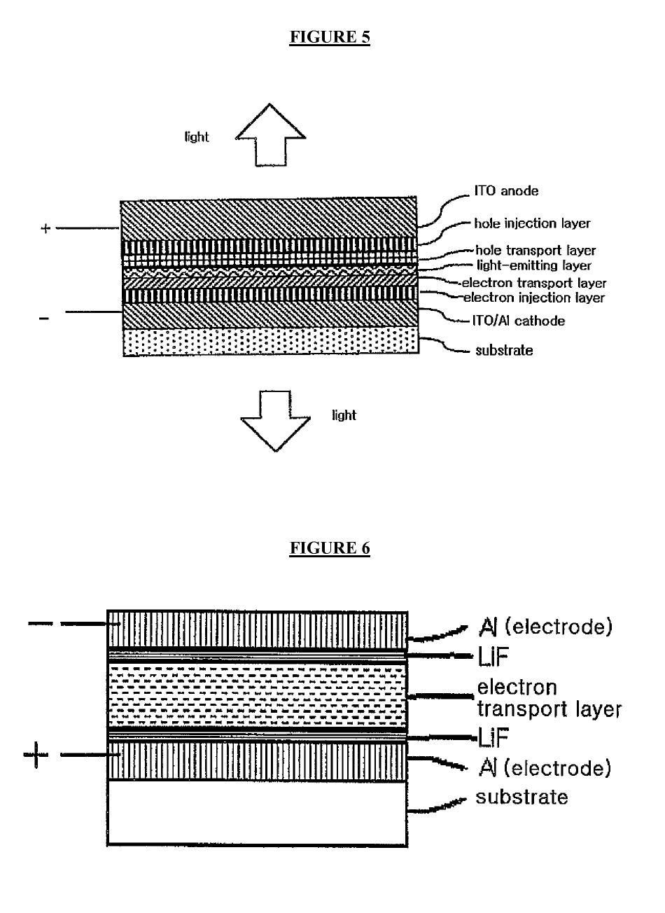

Examples of the organic electroluminescent device according to the present invention are shown in FIGS. 4 and 5. FIG. 4 illustrates a top emission type electroluminescent device, and FIG. 5 illustrates a both-side emission type electroluminescent device. However, it will be understood that the structure of the inventive organic electroluminescent device is not limited only to these structures.

The organic material layers in the inventive organic electroluminescent device may consist not only of the organic material layer comprising a compound having a functional group selected from the group consisting of an imidazole group, an oxazole group and a thiazole group and the light-emitting layer, but also, if necessary, of a multilayer structure comprising the organic material layer comprising the compound of formula 3 and additional organic material layers. For example, the inventive organic electroluminescent device may have a structure comprising a hole injection layer, a hole transport layer, a hole injection/transport layer, a light-emitting layer, an electron transport layer, an electron injection layer, a buffer layer formed between an anode and the hole injection layer, and the like as organic material layers. However, the structure of the organic electroluminescent device is not limited only to this structure and may comprise a smaller number of organic material layers.

The material of the cathode is preferably a material having a low work function to easily inject electrons to the LUMO energy level of the n-type organic compound layer such as the electron transport layer. Examples of the material of the cathode include a metal, such as magnesium, calcium, sodium, potassium, titanium, indium, yttrium, lithium, gadolinium, aluminum, silver, tin, and lead, or an alloy thereof; and materials having a multi-layer structure, such as LiF/Al or LiO₂/Al. Alternatively, the cathode may be formed of the same material as the anode. The cathode or the anode may contain a transparent material.

### MODE FOR INVENTION

Hereinafter, the present invention will be described in detail using examples. It is to be understood, however, that these examples are given for illustrative purpose only and are not to be construed to limit the scope of the present invention.

### EXAMPLES

### Example 1

On a glass substrate, a cathode (Al) having a thickness of 150 nm and an electron injection layer (LiF) having a thickness of 1.5 nm were sequentially formed by a thermal evaporation process. Then, on the electron injection layer, an electron transport layer consisting of a thin film made of the material comprising imidazole group represented by the following formula 1-1 comprising an imidazole group was formed to a thickness of 150 nm.

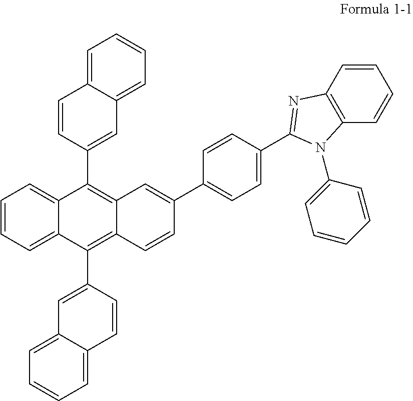

On the electron transport layer, an electron injection layer (LiF) having a thickness of 1.5 nm and Al layer having a thickness of 150 nm were formed sequentially to fabricate a symmetrical-type device as shown in FIG. 6 in which electric current runs only through electrons.

### Comparative Example 1

A symmetrical-type device, as shown in FIG. 6 in which electric current runs only through electrons, was fabricated in the same manner as described in Example 1, except that Alq3 in place of the compound comprising an imidazole group in Example 1.

The devices fabricated in Example 1 and Comparative Example 1 were symmetrical-type devices having the structure of Al—LiF-electron transport material-LiF—Al, in which the electric current running through the electron transport material is generated only by electrons.

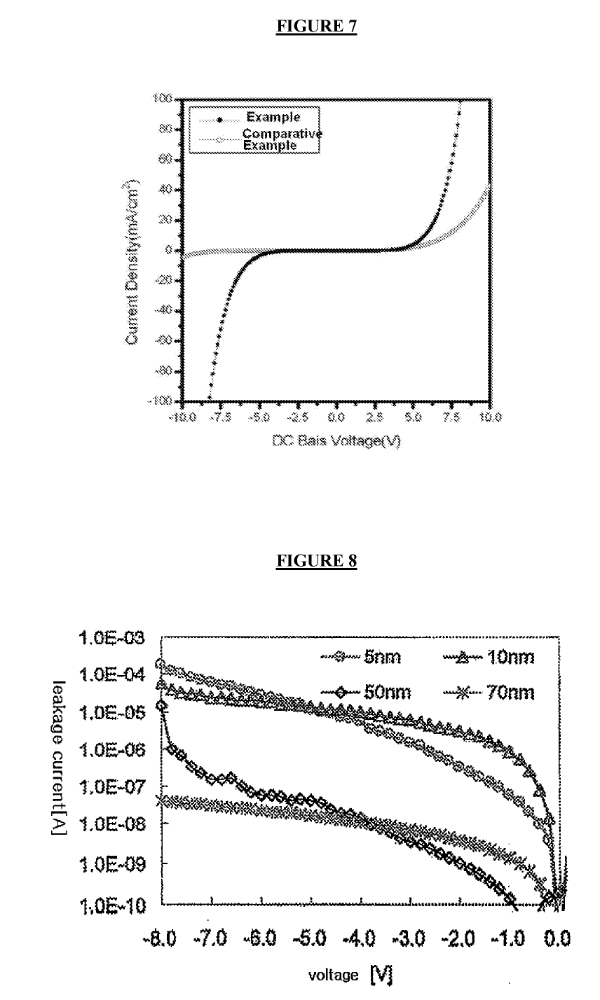

FIG. 7 shows current-voltage characteristic in Example 1 and Comparative Example 1. In FIG. 7, the positive voltage shows electron injection from top Al electrode to the electron transport layer and the negative voltage shows electron injection from bottom Al electrode to the electron transport layer. In Comparative Example 1 that used Alq3 which is frequently used in organic electroluminescent device as an electron transport material, electron injection from top Al electrode took place very well while electron injection from bottom Al electrode did not take place very well in spite of a symmetrical-type device. On the other hand, in Example 1 that used the compound comprising an imidazole group as an electron transport material, current voltage characteristic is symmetrical and this means that electron injection from both of top Al electrode and bottom Al electrode to the electron transport layer took place very well.

The reason that the electron injection from the bottom electrode to the electron transport layer took place more effectively through the compound comprising an imidazole group than Alq3 is considered as the reactivity of imidazole group in the compound of formula 1-1 to Li ion in Li-fluoride (LiF) is larger than that of Alq3. Accordingly, when a material having a group of a large reactivity to Li ion, such as, the imidazole group, is used as an electron transport material, electron injection characteristic from bottom electrode to electron transport layer can be improved.

The above results show that, if an electron transport material comprising an imidazole group, or an oxazole or thiazole group having similar properties to the imidazole group, as described above, is used, an organic electroluminescent device having improved electron injection characteristic can be provided, since an organic electroluminescent device having an inverted structure requires electron injection from bottom electrode to electron transport layer.

### Examples 2-6

### Fabrication of Organic Electroluminescent Device

On a glass substrate, a cathode (Al) having a thickness of 150 nm and an electron injection layer (LiF) having a thickness of 1.5 nm were sequentially formed by a thermal evaporation process. Then, on the electron injection layer, an electron transport layer consisting of a thin film made of a material comprising an imidazole group used in Example 1 was formed to a thickness of 20 nm.

Then, on the electron transport layer, an Alq₃ light-emitting host was co-deposited with C545T (10-(2-benzothiazolyl)-1,1,7,7-tetramethyl-2,3,6,7-tetrahydro-1H,5H,11H-1)benzopyrano[6,7,8-ij]quinolizin-11-one) to form a light-emitting layer having a thickness of 30 nm. On the light-emitting layer, a hole transport layer consisting of a thin film made of NPB (4,4′-bis[N-(1-napthyl)-N-phenylamino]biphenyl) was deposited to a thickness of 40 nm. On the hole transport layer, a hole injection/buffer layer made of a compound (HAT) represented by the following formula 3-1 was formed to a thickness of 5 nm (Example 2), 10 nm (Example 3), 20 nm (Example 4), 50 nm (Example 5) or 70 nm (Example 6):

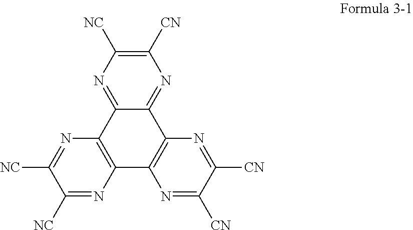

On the buffer layer, an IZO anode having a thickness of 150 nm was formed by a sputtering process at a rate of 1.3 Å/sec, thus fabricating a top emission type organic electroluminescent device.

### Example 7

### Fabrication of Organic Electroluminescent Device

A both-side emission type organic electroluminescent device was fabricated in the same manner as described in Examples 2-6 except that a cathode consisting of a thin Al film having a very small thickness of 5 nm formed on an ITO film having a thickness of 150 nm is used in place of the cathode consisting of the thin Al film having a thickness of 150 nm.

[Measurement of Current-Voltage Characteristics and Light Emission Characteristics of Device]

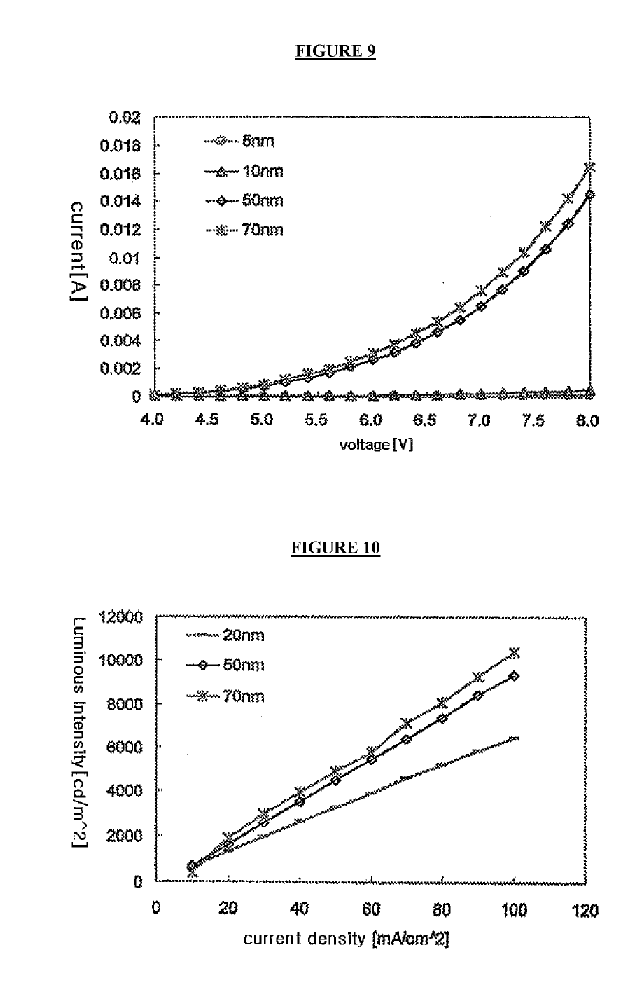

To the organic electroluminescent device fabricated in Examples 2-6, each of reverse and forward electric fields was applied at a voltage increasing at increments of 0.2 volts while current at each voltage value was measured. The measurement results are shown in FIGS. 8 and 9, respectively.

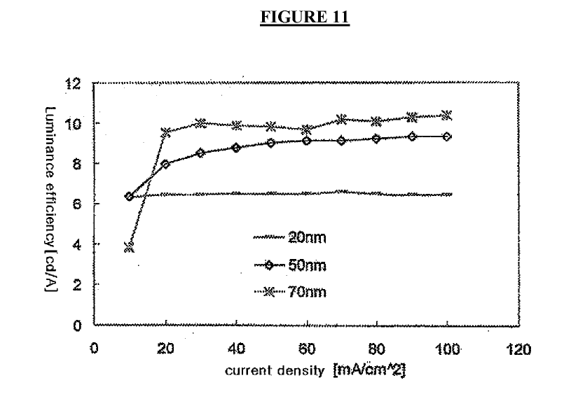

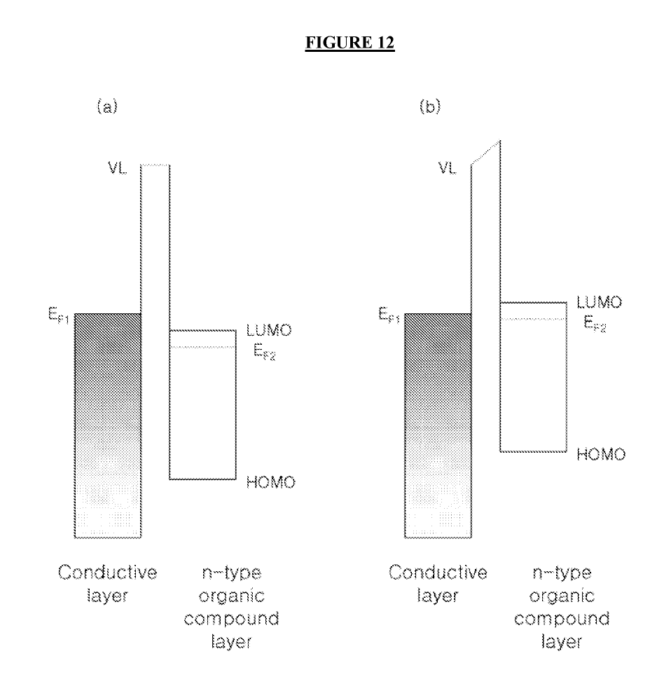

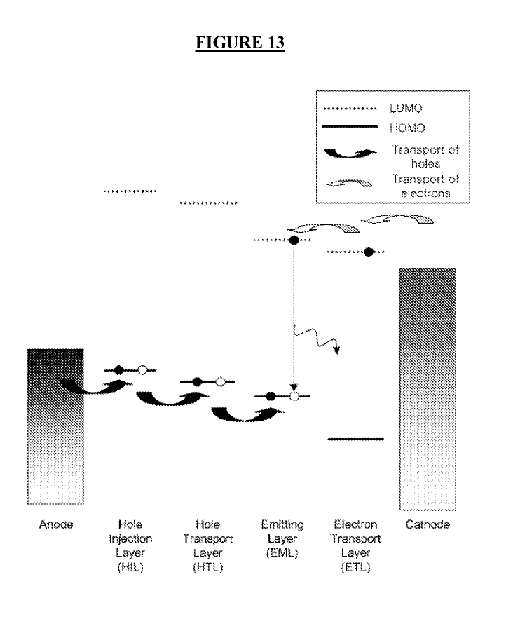

Also, to the organic electroluminescent device fabricated in Examples 4-6, current was applied while gradually increasing current density from 10 mA/cm² to 100 mA/cm², and at the same time, the luminous intensity of the device was measured using photometry. The measurement results are shown in FIGS. 10 and 11.

In organic electroluminescent devices, damage to an organic material layer occurring in the formation of an electrode leads to deterioration in current-voltage characteristics and light emission characteristics. Thus, the current-voltage characteristics and light emission characteristics shown in FIGS. 8 to 11 indicate that the compound of formula 3 has the effect of preventing damage to the organic material layer.

More particularly, FIGS. 8 and 9 show the current-voltage characteristics of the organic electroluminescent device as a function of the thickness of the organic material layer comprising the compound of formula 3. It is known that when an organic material layer in contact with the anode located opposite the substrate is made of an organic material, which has been generally used in the prior organic electroluminescent device, an organic electroluminescent device comprising this organic material layer will not show normal rectification and light emission characteristics due to the damage to the organic material layer, which occurs when forming the anode on the organic material layer by sputtering. However, as shown in FIGS. 8 and 9, the inherent characteristics (e.g., rectification characteristic) of the organic electroluminescent device were clearly shown as the thickness of the organic material layer made of the compound of formula 3 increased.

Regarding a reverse current-voltage characteristic shown in FIG. 8, the case of forming the organic material layer comprising the compound of formula 3 to a thickness of about 5-10 nm showed little improvement in the leakage current of the device, and the case of forming the buffer layer to a thickness of more than 50 nm showed a remarkable improvement in the leakage current of the device, indicating a very clear rectification characteristic. Regarding a forward current-voltage characteristic shown in FIG. 9, when the thickness of the layer made of the compound of formula 3 was increased from 10 nm to 50 nm, current was consequently increased rapidly.

Furthermore, as shown in FIG. 10, a light emission characteristic was also improved in proportion to an increase in the current as described above. Regarding luminance efficiency shown in FIG. 11, an increase in the thickness of the organic material layer comprising the compound of formula 3 showed a remarkable increase in luminance efficiency. This is attributable to the effect of the buffer layer of preventing sputtering damage.

What is claimed is:

1. An organic electroluminescent device comprising a substrate, a cathode, at least three organic material layers comprising a light-emitting layer, and an anode in the sequentially laminated form, in which the organic material layers comprise an n-type organic material layer positioned between the cathode and the light-emitting layer; and an organic material layer comprising a compound having a functional group selected from the group consisting of an imidazole group, an oxazole group and a thiazole group between the cathode and the light-emitting layer.

2. The organic electroluminescent device of claim 1, wherein the n-type organic layer is in contact with the anode.

3. The organic electroluminescent device of claim 2, energy levels of the n-type organic material layer and the anode satisfy the following Expression (1):
E_{nL}−E_{F1}≦4 eV (1)
In the Expression (1), E_{F1} is a Fermi energy level of the anode, E_{nL} is an LUMO energy level of the n-type organic material layer.

4. The organic electroluminescent device of claim 3, the Expression (1) satisfy the following Expression:
2 eV<E_{nL}−E_{F1}≦4 eV.

5. The organic electroluminescent device of claim 1, the organic electroluminescent device further comprises a p-type organic material layer that is interposed between the n-type organic material layer and the light-emitting layer and forms an NP junction together with the n-type organic material layer.

6. The organic electroluminescent device of claim 5, energy levels of the n-type organic material layer and the p-type organic material layer satisfy the following Expression (2):
E_{pH}−E_{nL}≦1 eV (2)
In the Expression (2), E_{nL} is an LUMO energy level of the n-type organic material layer and E_{pH} is an HOMO energy level of the p-type organic material layer forming the NP junction together with the n-type organic material layer.

7. The organic electroluminescent device of claim 1, wherein the compound having a functional group selected from the group consisting of an imidazole group, an oxazole group and a thiazole group includes a compound represented by the following formula 1 or 2: 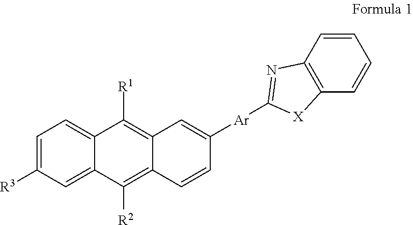
wherein, R¹ and R² may be the same or different from each other, and are each respectively selected from the group consisting of hydrogen, aliphatic hydrocarbons of 1-20 carbon atoms, aromatic rings and aromatic heterocyclic rings; Ar is selected from the group consisting of aromatic rings and aromatic heterocyclic rings; R³ is selected from the group consisting of hydrogen, aliphatic hydrocarbons having 1-6 carbon atoms, aromatic rings and aromatic heterocyclic rings; and X is selected from the group consisting of O, S and NR¹¹ wherein R¹¹ is selected from the group consisting of hydrogen, aliphatic hydrocarbons of 1-7 carbon atoms, aromatic rings and aromatic heterocyclic rings, provided that both of R¹ and R² are not hydrogen at the same time, and 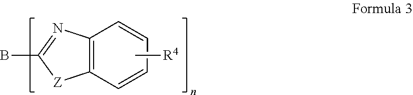
wherein Z is O, S or NR²²; R⁴ and R²² are respectively hydrogen, alkyl of 1-24 carbon atoms, aryl or hetero-atom substituted aryl of 5-20 carbon atoms, halogen atoms, or alkylene or alkylene comprising a hetero-atom necessary to complete a fused ring with a benzazole ring; B is a linkage unit consisting of alkylene, arylene, substituted alkylene, or substituted arylene, which conjugatedly or unconjugately connects the multiple benzazoles together; and n is an integer from 3 to 8.

8. The organic electroluminescent device of claim 1, wherein the organic material layer comprising a compound having a functional group selected from the group consisting of an imidazole group, an oxazole group and a thiazole group is an electron transport layer.

9. The organic electroluminescent device of claim 1, the n-type organic material layer comprises a compound represented by the following formula 3: 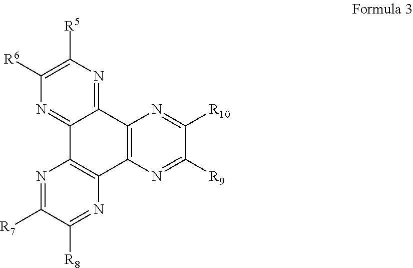
wherein, R⁵ to R¹⁰ are each respectively selected from the group consisting of hydrogen, halogen atoms, nitrile (—CN), nitro (—NO₂), sulfonyl (—SO₂R³¹), sulfoxide (—SOR³¹), sulfonamide (—SO₂NR³¹), sulfonate (—SO₃R³¹), trifluoromethyl (—CF₃), ester (—COOR³¹), amide (—CONHR³¹ or —CONR³¹R³²), substituted or unsubstituted straight or branched C₁-C₁₂ alkoxy, substituted or unsubstituted straight or branched C₁-C₁₂ alkyl, substituted or unsubstituted aromatic or non-aromatic heterocyclic rings, substituted or unsubstituted aryl, substituted or unsubstituted mono- or di-arylamine, and substituted or unsubstituted aralkylamine, and R³¹ and R³² are each respectively selected from the group consisting of substituted or unsubstituted C₁-C₆₀ alkyl, substituted or unsubstituted aryl, and substituted or unsubstituted 5- to 7-membered heterocyclic rings.

10. The organic electroluminescent device of claim 1, wherein the n-type organic material layer comprises a compound selected from compounds represented by the following formulas 3-1 to 3-6:

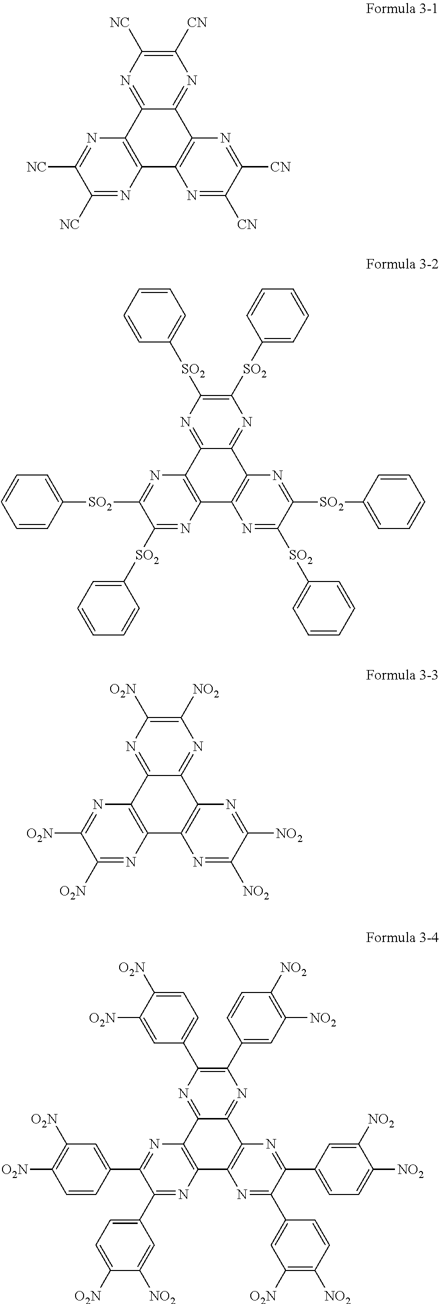

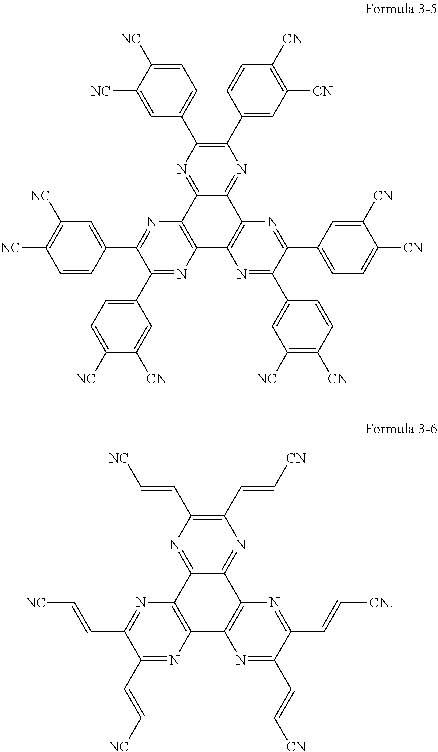

11. The organic electroluminescent device of claim 1, the n-type organic material layer comprises at least one compound selected from 2,3,5,6-tetrafluoro-7,7,8,8-tetracyanoquinodimethane (F4TCNQ), fluoro-substituted 3,4,9,10-perylenetetracarboxylic dianhydride (PTCDA), cyano-substituted 3,4,9,10-perylenetetracarboxylic dianhydride (PTCDA), naphthalene-tetracarboxylic-dianhydride (NTCDA), fluoro-substituted naphthalene-tetracarboxylic-dianhydride (NTCDA), or cyano-substituted naphthalene-tetracarboxylic-dianhydride (NTCDA).

12. The organic electroluminescent device of claim 1, wherein the organic electroluminescent device is a top emission type or both-side emission type device.

13. The organic electroluminescent device of claim 9, wherein the anode is formed by thin-film formation technology capable of causing damage to the organic material layer in contact with the anode by involving charges or particles with high kinetic energy.

14. The organic electroluminescent device of claim 13, wherein the thin-film formation technology is selected from the group consisting of sputtering, physical vapor deposition (PVD) using a laser, and ion-beam assisted deposition.

15. The organic electroluminescent device of claim 9, wherein the anode is made of a metal or metal oxide having work function of 2-6 eV.

16. The organic electroluminescent device of claim 9, wherein the anode is made of ITO or IZO.

17. The organic electroluminescent device of claim 9, wherein the n-type organic material layer also serves as a hole injection layer.

18. The organic electroluminescent device of claim 9, wherein the n-type organic material layer has a thickness of equal to or more than 20 nm.

19. The organic electroluminescent device of claim 1, wherein a thin oxide film having an insulating property is additionally formed between the anode and the n-type organic material layer.

20. The organic electroluminescent device of claim 8, wherein an electron injection layer is formed between the cathode and the electron transport layer.

21. The organic electroluminescent device of claim 1, additionally comprising a hole injection layer, a hole transport layer, or a hole injection and transport layer between the light-emitting layer and the anode.
